(19) United States
(12) Patent Application Publication
(10) Pub. No.: US 2024/0339843 A1
(43) Pub. Date: Oct. 10, 2024

(54) SYSTEM AND METHOD OF LITHIUM PLATING REVERSAL

(71) Applicant: Iontra Inc, Centennial, CO (US)

(72) Inventors: Daniel A. KONOPKA, Aurora, CO (US); Zhong WANG, Sugar Land, TX (US)

(21) Appl. No.: 18/621,049

(22) Filed: Mar. 28, 2024

Related U.S. Application Data
(63) Continuation-in-part of application No. 18/127,634, filed on Mar. 28, 2023.
(63) Continuation-in-part of application No. 18/619,129, filed on Mar. 27, 2024.
Application No. 18/619,129 is a continuation-in-part of application No. 18/127,634, filed on Mar. 28, 2023.
(60) Provisional application No. 63/455,254, filed on Mar. 28, 2023.
(60) Provisional application No. 63/540,924, filed on Sep. 27, 2023.
(60) Provisional application No. 63/542,504, filed on Oct. 4, 2023.
(60) Provisional application No. 63/324,505, filed on Mar. 28, 2022.
(60) Provisional application No. 63/454,932, filed on Mar. 27, 2023.
(60) Provisional application No. 63/540,924, filed on Sep. 27, 2023.
(60) Provisional application No. 63/542,504, filed on Oct. 4, 2023.
(60) Provisional application No. 63/455,254, filed on Mar. 28, 2023.
(60) Provisional application No. 63/324,505, filed on Mar. 28, 2022.

(51) Int. Cl. H02J 7/00; G01R 31/3842; H01M 10/42; H01M 10/44; H01M 10/48

(52) U.S. Cl. CPC H02J 7/00041; G01R 31/3842; H01M 10/44; H01M 10/48; H01M 2010/4271

(57) ABSTRACT

Aspects of the present disclosure analyzing one or more signals that include both uncorrelated random signals as well as correlated information pertaining to electrochemical and/or electrodynamic processes occurring within a battery, characterizing the battery for charging, discharging, storage and other uses and/or controlling charging, discharging and other aspects of battery management based on the same.

### CROSS-REFERENCE TO RELATED APPLICATION

The present application is a Non-Provisional Utility patent application related to and claiming priority under 35 U.S.C. § 119 (e) to U.S. Provisional Application No. 63/455,254 filed Mar. 28, 2023, titled “System and Method of Time-Series Analysis of Noisy Appearing Signals for Battery Charging,” the entire contents of which is incorporated herein by reference for all purposes.

The present application is a Non-Provisional Utility patent application related to and claiming priority under 35 U.S.C. § 119 to U.S. Provisional Application No. 63/540,924 filed Sep. 27, 2023 and U.S. Provisional Application No. 63/542,504 filed Oct. 4, 2023, each titled “Electrodynamic Parameters,” both of which are hereby incorporated by reference herein.

The present application is a Continuation-in-Part patent application related to and claiming priority to U.S. Non-Provisional application Ser. No. 18/127,634 filed Mar. 28, 2023, titled “System and Method of Time-Series Analysis of Noisy Appearing Signals for Battery Charging,” which claims benefit of priority under 35 U.S.C. § 119 (e) from U.S. Provisional Application No. 63/324,505, filed Mar. 28, 2022, titled “Noise,” both of which are hereby incorporated by reference in their entirety.

The present application is a Continuation-in-Part patent application related to and claiming priority to U.S. Non-Provisional application Ser. No. 18/619,129 filed Mar. 27, 2024, titled “Electrodynamic Parameters,” which claims benefit of priority under 35 U.S.C. § 119 (e) to U.S. Provisional Application No. 63/454,932 filed Mar. 27, 2023, titled “System and Method for Deterministic Analysis of Batteries, and Characterization and Charging Based on the Same,” to U.S. Provisional Application No. 63/540,924 filed Sep. 27, 2023, titled “Electrodynamic Parameters,” to U.S. Provisional Application No. 63/542,504 filed Oct. 4, 2023, titled “Electrodynamic Parameters,” to U.S. Provisional Application No. 63/455,254 filed Mar. 28, 2023, titled “System and Method of Time-Series Analysis of Noisy Appearing Signals for Battery Charging,” and is a Continuation-in-Part patent application related to and claiming priority to U.S. patent application Ser. No. 18/127,634 filed Mar. 28, 2023, titled “System and Method of Time-Series Analysis of Noisy Appearing Signals for Battery Charging,” which claims benefit of priority under 35 U.S.C. § 119 from U.S. Provisional Application No. 63/324,505 filed Mar. 28, 2022, titled “Noise,” all of which are hereby incorporated by reference in their entirety.

### TECHNICAL FIELD

Aspects of the present disclosure analyzing one or more signals that include both uncorrelated random signals as well as correlated information pertaining to electrochemical and/or electrodynamic processes occurring within a battery, characterizing the battery for charging, discharging, storage and other uses and/or controlling charging, discharging and other aspects of battery management based on the same.

### BACKGROUND and INTRODUCTION

Battery powered devices have proliferated and become ubiquitous. Device manufactures are constantly pressing for performance improvement in batteries, particularly as batteries are introduced into devices with relatively higher current demands and power needs. At the same time, consumers demand longer battery life, longer times between charges, and shorter charge times. As such, there is an ongoing and continuous need for improvements in how batteries are managed, charged and discharged to enhance performance. It is with these observations in mind, among many others, that the various aspects of the present disclosure were conceived.

### SUMMARY

Aspects of the present disclosure involve a method comprising accessing a noisy signal from a battery where the noisy signal includes uncorrelated noise and correlated signal data and filtering the noisy signal to isolate the correlated signal data. The method further involves processing the correlated signal data to identify at least one of an electrochemical or electrodynamic process within the battery. In various possible implementations, the noisy signal is a voltage measurement or a current measurement at the battery. The signal may also be accessed from memory. The noisy signal may also be a generated measurement, such as an impedance measurement (determination) from at least one of a current measurement and a voltage measurement.

The signal may be obtained during an equilibrium state of the battery, which may be during charge or discharge, or from a probe signal. The equilibrium state of the battery may be considered and occur during a zero-net change to the battery. The signal may also be obtained in a transient state of the battery, which may be associated with a charge signal or a discharge signal. The method may further include filtering the noisy data, such as by way of a domain transform or other filtering technique, to identify the correlated signal data. The domain transform may be one of a partial or fractional domain transform.

The correlated signal data may be associated with plating, and/or dendrite formation and growth. More generally, the correlated signal data may be associated with electrodynamic behavior in the battery. As such, the system and methods discussed herein may act on the identification of electrodynamic behavior of the battery. Conversely, the uncorrelated signal data may be thermal, which can be seen as noise, and hence removing thermal information may help isolate the correlated signal data.

In various possible aspects processing the correlated signal data may involve identifying a bifurcation where a bifurcation is indicative of the onset of an additional electrochemical or electrodynamic process, such as intercalation following by plating being the additional process.

The method may further involve altering a charge parameter (or discharge parameter) based on the identification of the electrochemical or electrodynamic process within the battery.

Another aspect of the present disclosure involves a method comprising, from a signal of an electrochemical device including uncorrelated data and correlated data including pertaining to electrochemical or electrodynamic process of the electrochemical device, filtering the signal to identify the correlated data including information pertaining to the electrochemical or electrodynamic process; and altering a charge parameter based, at least in part, on identification of a bifurcation in the filtered signal. The electrochemical device may be a battery and the signal may be obtained, e.g., measured, during charge or discharge. The charge parameter that is altered may be charge rate, charge voltage and/or duty cycle depending on the type of charge signal. The charge parameter may also comprise a harmonic component of the charge signal.

Another aspect of the present disclosure involves a method comprising accessing a noisy signal from a battery, the noisy signal including uncorrelated noise and correlated signal data; filtering the noisy signal to isolate the correlated signal data; processing the correlated signal data to identify plating within the battery; and initiating at least one of reducing charge, stopping charge, discharging the battery or generating an electric field to at least partially stop or reverse plating. The noisy signal may be a voltage measurement and/or a current measurement. The correlated signal data may be associated with plating. The correlated signal data may also be associated with dendrite formation and growth.

The method may further involve processing the correlated signal data to identify a bifurcation, the bifurcation indicative of the onset of an additional electrochemical or electrodynamic process.

Another aspect of the present disclosure may involve a method comprising: from a signal of an electrochemical device including uncorrelated data and correlated data including pertaining to electrochemical or electrodynamic process of the electrochemical device, filtering the signal to identify the correlated data including information pertaining to the electrochemical or electrodynamic process; and altering a charge parameter based, at least in part, on identification of a bifurcation in the filtered signal. The electrochemical device may be a battery. The signal may be measured during charge or discharge. The correlated data may pertain to, at least in part, plating of the anode and altering the charge parameter reduces or reverses plating.

Another aspect of the present disclosure involves a method of managing plating in a battery comprising: from a signal of a battery, computing a Lyapunov Exponent; and initiating at least one of stopping charge of the battery, discharging the battery, or generating an electric field across the battery upon identifying that the Lyapunov Exponent has met a threshold associated with chaotic behavior. In some examples, the threshold is a value of 0. The signal is a voltage signal, in some instances, and the signal may be responsive to a probe signal to the battery.

Discharging the battery to reverse plating and responsive to LE may involve a duration of between 30 seconds and 3 minutes, after which charging of the battery may resume if charging was underway. In other instances, the system stops charge which is followed by a discharge pulse. Charging may proceed at a reduced magnitude after a plating reversal sequence.

These and other aspects of the disclosure are described in further detail below.

### BRIEF DESCRIPTION OF THE DRAWINGS

FIG. 1 is a diagram of probe signal, which may also be a shaped charging signal, illustrating a transient time A when data may be sampled for further processing and steady state times B and/or C when data may also be sampled for further processing.

FIG. 2 is an example of a signal captured at a transient time A of FIG. 1.

FIG. 3 is an example of bifurcation and Lyapunov constant diagrams generated in accordance with aspects of the present disclosure and reflective of electrochemical and electrodynamic battery cell processes, and part of generating information and actions concerning the same.

FIG. 4 is a flow diagram of a one method of detecting the onset of plating and initiating a plating reversal sequence, according to one embodiment.

FIG. 5(A) is a diagram illustrating battery terminal current measurements for a probing waveform.

FIG. 5(B) is a diagram illustrating battery terminal voltage measurements for the probing waveform of FIG. 5(a).

FIG. 6(A) illustrates Lyapunov Exponent computations at different charging waveforms using data gathered from a probing waveform like illustrated in FIGS. 5(A) and 5(B).

FIG. 6(B) illustrates the LE computations of FIG. 6(a) normalized [−1,1] and divided by minimum current for the respective charge rates (1C, 3C and 5C).

FIG. 7 illustrates an example of LE calculation and the effect of temperature on anode overpotential as reflected in LE values.

FIG. 8 illustrates the correlation between LE calculation and anode overpotential for a multi-step charging process.

FIG. 9 shows a block diagram of a battery system 900 including a controller, which may detect anode overpotential by way of electrodynamic parameters such as LE, and initiate and control a plating reversal sequence based on the same.

FIG. 10 is a diagram illustrating various possible lithium plating reversal sequences.

FIG. 11 is a diagram illustrating current and voltage measurements for a CCCV charge scheme and conventional period of discharge for a battery.

FIG. 12 is a diagram illustrating current and voltage measurements for a CCCV charge scheme and further incorporating a plating reversal sequence in the form of a discharge pulse at the end of charge followed by a conventional period of discharge.

FIG. 13 is a plot of coulombic efficiency data of a cell charged and discharged according to the technique of FIG. 11 versus the same type of cell charged and discharged with a lithium plating reversal sequence pursuant to the technique of FIG. 12, the plot showing a capacity degradation over cycles more in the FIG. 11 battery versus the FIG. 12 battery.

FIG. 14 is one example of a computer system that may be used to implement the methods discussed herein.

### DETAILED DESCRIPTION

Aspects of the present disclosure involve a new understanding that electrodynamic and electrochemical processes in electrochemical systems, particularly rechargeable batteries, may be identified from what would normally be considered discardable data. In a general sense, “noise” in electrical systems is considered to consist of uncorrelated completely random signal data and is typically ignored or efforts are made to suppress or remove it. In the present application, however, signals that would normally be considered noisy are understood to contain information that may be associated with events occurring in the battery. The detection of such events and the manipulation of such signals, alone or in combination, may be further used to alter various actions on the battery such as charging or discharging. While aspects of this disclosure are discussed primarily in the context of battery charging and discharging, aspects of the disclosure are also applicable to other environments including electroplating systems.

The term “battery” in the art and herein can be used in various ways and may refer to an individual cell having an anode and cathode separated by an electrolyte, solid or liquid, as well as a collection of such cells connected in various arrangements. A battery or battery cell is a form of electrochemical device. Batteries generally comprise repeating units of sources of a countercharge and electrode layers separated by an ionically conductive barrier, often a liquid or polymer membrane saturated with an electrolyte. These layers are made to be thin so multiple units can occupy the volume of a battery, increasing the available power of the battery with each stacked unit. Although many examples are discussed herein as applicable to a battery, it should be appreciated that the systems and methods described may apply to many different type of batteries ranging from an individual cell to batteries involving different possible interconnections of cells such as cells coupled in parallel, series, and parallel and series. For example, the systems and methods discussed herein may apply to a battery pack comprising numerous cells arranged to provide a defined pack voltage, output current, and/or capacity. Moreover, the implementations discussed herein may apply to different types of electrochemical devices such as various different types of lithium batteries including but not limited to lithium-metal and lithium-ion batteries, lead-acid batteries, various types of nickel batteries, and solid-state batteries, to name a few. The various implementations discussed herein may also apply to different structural battery arrangements such as button or “coin” type batteries, cylindrical cells, pouch cells, and prismatic cells.

To begin, an unfiltered signal, which may appear noisy, or carefully filtered signal is captured from the battery. For example, the system may include a filter or filters targeted at filtering out readily identified hardware or other forms of ancillary noise. Stated differently, the filter or filters may be set or defined to remove signal data that is known to be related to hardware and environmental contributions (e.g., thermal effects) and not be related to battery dynamics, such as internal battery electrodynamics. The signal may be captured during steady state (equilibrium). The signal may also be captured in the presence of a probe signal. The probe signal may be a dedicated probing signal or may be a charge signal. The signal may also be captured during discharge. In one specific example, the probe signal is a charge signal and includes transient portions and steady state portions.

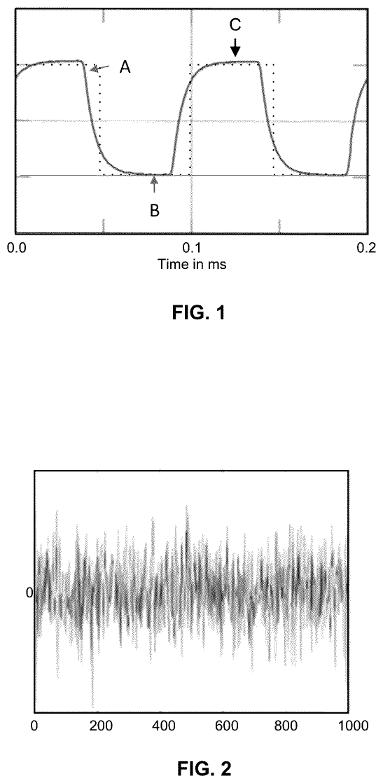

FIG. 1 illustrates an example charge signal that includes a transient portion at A and relatively steady state portions at B and C. A probe signal may similarly have transient and/or steady portions. The y-axis in this diagram is voltage ranging from about 0 (versus open circuit at the battery terminals) to about 5 volts for many conventional single Lithium-Ion cells with an open circuit voltage of about 4.2 volts although it can be higher; however, it may also be current and display a similar waveform. The upper voltage range is dependent on a number of factors and the example here is merely provided for relative reference. As seen at locations B and C, the signal is at a steady state voltage if even only for about 0.25 ms. At location A, in contrast, the signal rapidly drops from a first steady state to a lower second steady state over a time of about 0.25 ms, with the transition area, between steady states, being transient. Data may be captured at time A and/or at time B and/or at time C. Of note, the charge signal here is tailored to not include any sharp high frequency charge edges associated with pulse charging, which would be in the form of a square wave (shown in dashed line for comparative purposes) with about 90 degree transitions and is not considered pulse charging. Techniques discussed herein, however, may be used to modify pulse charging signals. Data may also be captured at other points, with A, B and C simply being examples. In the example signal, A is a point immediately following the cessation of charge current but while the charge voltage is beginning to descend to zero after the cessation of charge current. Point B is at a point after the charge current and charge voltage are about zero and before the initiation of a subsequent charge energy. C indicates an actively controlled and stimulated point of current and voltage.

FIG. 2 is an illustration of a signal captured at point A. Data captured at point B will have a similar quality albeit will include information associated with a temporary steady state as opposed to transient processes within the cell. Similarly, data at point C will contain information about processes associated with electrical activity inside the cell concurrent with a particular current and potential.

More particularly and as introduced above, within the noisy appearing data includes correlated signals masquerading as uncorrelated noise. This correlated data is captured with the uncorrelated information. The correlated (deterministic) signals are associated with electrochemical and electrodynamic processes occurring within the battery. As such, and in accordance with aspects of the present disclosure, a myriad of useful information may be obtained by isolating the correlated information, associating that information with some event occurring in the battery, and/or then acting on that information and event correlation to alter charge, discharge, characterization parameters or other actions on or in relation to the battery. Conventionally, there has not believed to have been a recognition that there is an association between electrochemical and electrodynamic information and correlated signal character hidden within complex noise. Similarly, there has not been any attempt to use such information to manage electrical energy used to charge or discharge a battery, electroplate or otherwise.

In one example, during equilibrium (steady state), when there is no charge or discharge of the battery, there are some electrochemical processes occurring involving ion diffusion, intercalation and deintercalation, for example. Typically, there are no net changes associated with such equilibrium activity. These steady state processes are nonetheless reflected in and can be identified from correlated signals that may be isolated from and otherwise detected in the measured signal.

In another example, correlated signals within the broader data signal may be reflective of lithium plating and may be used to identify such events. Lithium plating can lead to dendrite growth among other concerns. During charging, lithium ions from the cathode insert into the anode in a process referred to as intercalation. At the same time, lithium may plate the anode, which is undesirable and can lead to various problems including capacity degradation and increased internal cell resistance. Dendrite growth can be associated with capacity degradation and also further lead to short circuit conditions, which may lead to battery failure. There are some known causes for plating including charging at a rate that exceeds the rate at which some ions can intercalate (a rate considered too high) and charging at too low a temperature where ions cannot efficiently intercalate. Besides altering a charge signal, upon determination of the onset of plating, the system may also wait until temperature increases to an acceptable threshold to resume charging.

In accordance with aspects of the present disclosure, it has been further discovered that plating, including dendrite formation and growth, may also be caused or exacerbated by uncontrolled charge signal noise, particularly relatively high frequency charge signal noise. This noise may originate from processes inside the cell, from external sources such as nearby electrical components or radiating signals, or from frequent alternation between net charge and discharge states, and other sources. Uncontrolled charge signal noise is seen to be associated with electrodynamic effects and conductive pathway concentration in the anode, cathode, and/or associated current collectors. The electrodynamic noise induced conductive pathways may then cause localized current concentrations leading to plating and dendrite formation. Aspects of the present disclosure thus involve identifying such conditions, and countering or otherwise mitigating uncontrolled noise.

To address some or all of these issues, as well as others, one particular aspect of the present disclosure involves identifying plating within the unaltered or carefully altered (e.g., filtered, as discussed above) signal and further may involve altering some condition (e.g., some aspect of the charge signal) to reduce or eliminate plating. The ability to detect plating in the correlated data, which may be a part of an otherwise noisy signal with uncorrelated data, may be based, at least in part, by the realization that plating and dendrite formation and growth are 3-dimensional, and sometimes fractal in nature. Filtering signal data to isolate or otherwise identify the correlated content, and then further processing, which may involve various assessments of statistical and deterministic nature, may be used to identify plating and act on it.

In terms of state of charge and as introduced above regarding plating, charging involves ion diffusion from the cathode to the anode. As the state of charge rises, the diffusion patterns change as available ions in the cathode and the intercalation activity at the anode declines. This activity is reflected in correlated signals within signal the data from a battery, related to both electrochemical and electrodynamic processes, and may thus be identified according to the techniques discussed herein.

While many processes are in play within a battery while it is being charged, in one example, one favorable and what might be considered normal and harmless process within the battery involves ion diffusion from the cathode to the anode. As mentioned above, under some unfavorable charge conditions, plating and dendrite growth may occur. It is also the case that as a battery approaches a full state of charge, the diffusive processes from the cathode to the anode reduce as the available lithium inventory lessens. The energy normally that would be going to battery healthy charging may then instead go into plating. In conventional processes because the electrokinetics of diffusion and plating are dependent and occur in series, the two processes are exceedingly difficult to distinguish and the onset of plating exceedingly difficult to distinguish from healthy charge transfer reactions. In one aspect of the present disclosure, however, correlated data during charge is processed to identify bifurcations. The onset of a bifurcation is representative of the onset of a distinct process within the data. In the case of correlated data extracted from a data signal during charge, a method may involve generating a bifurcation data set (commonly displayed as a bifurcation diagram) and identifying the occurrence of a bifurcation. Leading to the bifurcation may be indicative of change from healthy diffusion during charge and the transition to an additional process, such as plating, at the bifurcation indicative that charge energy is being used for both charging and plating. As such, upon the identification of a bifurcation, the system may alter the charge signal, such as by reducing the charge current, reducing the charge voltage, reducing both, altering a duty cycle, altering pulse characteristics, or making other charge signal changes.

Healthy cathodic phase changes may also occur during charging. Such a change may also be identified through a bifurcation. Assessing state of charge or acting on information during charging may be based on various parameters such as identifying the onset of plating and identifying cathodic phase changes, alone or in a myriad of combinations. For example, in the presence of a bifurcation related to the onset of plating, a charge signal may be reduced (e.g., reducing charge current), as noted above, to thereby reduce charge energy to have the effect of stopping plating. The system may then assess or assume that plating has been halted, and continue analyzing the correlated data until the onset of another bifurcation, and then repeat the process (altering charge parameters). It should be recognized that the process may be done in conjunction with an SOC assessment, or voltage level assessment, or other additional sets of information to identify when charging is complete—e.g., 100%.

The non-uniform plating and dendrite formation and growth, among other things, may be understood to be fractal in nature. Moreover, some processes and other battery processes that are fractal in nature are considered undesirable, while others may be considered normal and not damaging or otherwise undesirable. As such, correlated data within the signal may generally be characterized as fractal, which leads to opportunities to process the data as the same, and then associate the data with some undesirable or favorable processes within the cell. Moreover, when correlated signals are isolated from actual noise in the signal, the correlated signals may be processed using various statistical analytical techniques, some of which are directly or tangentially related to impedance and electrochemical physics, and others which are distinct from impedance-based parameters and reflective of broader electrodynamics. Numerous examples are possible including the generation of bifurcation data as discussed above and the generation of a Lyapunov exponent. Such may be correlated in relation to state of charge, state of health, instantaneous degradation, temperature distribution, voltage, current, impedance, and other useful metrics. Processing, alone or in various processing combinations, of the correlated signals yields information indicative of various desirable or otherwise normal electrochemical and electrodynamic processes as well as undesirable processes.

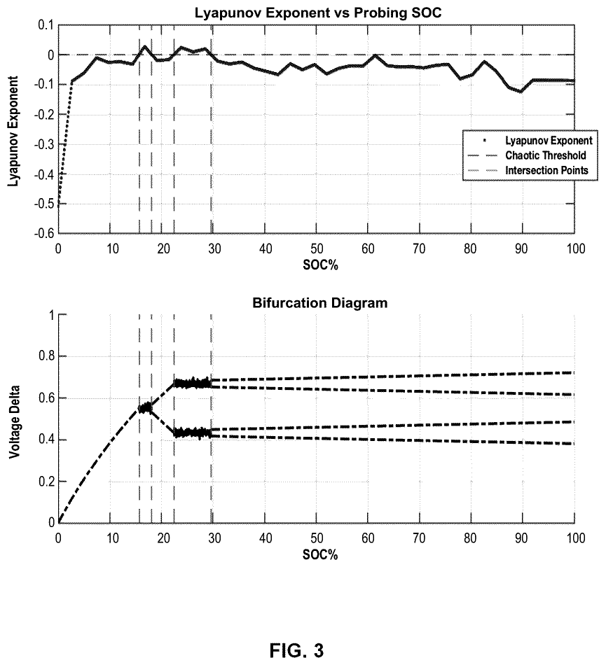

FIG. 3 is an example of a bifurcation diagram. In this example, the y-axis is voltage, although the same analysis could be performed with current or impedance, among other calculated, derived or referenced values, or combinations of values. The x-axis is State of Charge (SOC). In general, Lyapunov is a parameter that may be used to identify and qualify behaviors of correlated information within otherwise nonsensical data. Positive values indicate increasingly uncorrelated behavior. Negative values indicate periodic behavior. Values close to or at zero indicate the onset of chaotic behavior while trends which cross zero indicate at least a bifurcation in the measured parameter. Truly uncorrelated data such as noise or thermal processes are reflected by large positive values. In FIG. 3, the current is held at 2C during a complete charge cycle to show how the Lyapunov starts with periodic character which quickly becomes chaotic. Positive values are sustained for short periods, during which the activity in the cell, and at the electrodes, in particular, is irregular as portions of the electrode surface transition to a new mechanism of electron exchange. This phenomenon is measured nearly instantaneously and would go entirely unobserved in conventional impedance-based forms of analysis. As noted above, a bifurcation can imply the onset of two or more parallel pathways in the data. Above 20% SOC, the onset of a second pathway is identified. The pathways are continued to 100% SOC in this plot to indicate the battery's susceptibility. In practice, the detection of a bifurcation during charge would lead to quick adjustment of the charge signal, such as a decrease in current or voltage which would terminate the lithium plating pathway. This method, alone or combined with other analysis, may be used to detect the onset of lithium plating occurring parallel to intercalation associated with healthy charging and ion diffusion. Multiple parameters in combination can be used to identify key behaviors for any battery chemistry, size or architecture, as well as for electrochemical systems in general.

The information itself is valuable in characterizing a battery and is valuable in charge or discharge control of a battery, as well as other values, such as health generation of the battery (a process which is neither charging or discharging in a conventional sense). The information may also be useful in charge or discharge control. For example, detection of early onset plating, and modification of the charge signal to avoid the same contributes to longer battery cycle life, battery capacity, charge rate, capacity utilization, and battery safety among other things. Detection of state of charge has a myriad of similar advantages including greater battery capacity utilization, effective charge rate control, discharge control, greater cycle life, and battery safety overall.

### Lithium Plating Reversal

Lithium plating is a primary cause of battery degradation. Lithium plating, also known as lithium metal plating, occurs when lithium ions are deposited onto the anode surface during charging in a non-uniform and uncontrolled manner. Lithium plating reduces the number of lithium ions available for normal battery operation reducing battery capacity over time. Lithium plating can also lead to the formation of metallic lithium, which can accumulate on the anode surface and create dendritic structures. In some cases, the dendrites can pierce through the separator between electrodes, causing internal short circuits, and battery failure, which in some cases may also lead to thermal runaway.

Generally, lithium that plates onto the anode may be recoverable (that is, maintained in a metallic, dissolved, intercalated, or reversibly oxidized form (which may be electrolyte dependent)) through three mechanisms. First, if the applied current to the battery is sufficiently low and the graphite in proximity to the plated lithium is sufficiently vacant, then avoiding any increases in current or reducing the current, potentially to zero amps, can allow some or most of the plated lithium to continue intercalating into the graphite. Second, a sufficient magnitude of discharge current can cause some or most of the plated lithium to redissolve into the electrolyte. Third, in the case of metallic anodes or anodes which have taken on a degree of metallic character (such as in aged cells due to fast charging), an electric field in the direction of discharge may provide sufficient forces to remove or alter plated bodies of lithium, clear the electrode of obstruction and allow the lithium to proceed by either of the first two mechanisms.

In the third example, an electric field, distinct from a discharge pulse, may be generated across the cell. The discharge pulse (or pulses) may be used in coordination with the electric field. In one example, a potential difference, without a load on the battery to which current would normally flow, may be applied to the tabs of the battery cell generating an electric field that will cause at least some of the plated charged lithium particles on the anode to reverse. An electric field may also be generated with distinct charged surfaces (not the tabs, current collectors, and anode/cathode of the battery itself), e.g., one surface with a positive voltage (e.g., 100V) and the other surface grounded, and the battery positioned between the charged surfaces. The electric field may be applied for some period of time, e.g., 30 seconds, 1 minute, 2 minutes, etc. The electric field may also oscillate such that the field reverses. For example, one tab or other form of electrical connection point to the battery may be grounded and the other coupled to 100V. The field may then be reversed by applying the 100V to the formerly grounded tab, and grounding the tab that was formerly coupled with 100V. Reversing the field may happen one or more times depending on any given implementation. The voltage at the battery terminals may also be other values and the electric field may similarly be tailored to the type of battery, power available to generated the electric field, experimentation and other factors.

In another example, the field may involve alternating current which is capable of inducing electrokinetic effects on lithium bodies within the battery, particularly effects which act on dendritic and electrically detached lithium. In particular, AC electric fields may be tailored to induce AC electrophoresis or dielectrophoresis to polarize these lithium bodies for the purpose of inducing their physical movement toward the anode where they may potentially improve existing electrical contact (dendritic lithium) or reestablish electrical contact (detached lithium) and recover available lithium inventory. In addition to movement, strong electric fields may be induced to sufficiently polarize lithium bodies so as to cause electrochemical dissolution of isolated or insulated lithium mass back into the electrolyte.

In each of these cases, the yield of recovered lithium may be dependent upon how much time the exterior-most lithium atoms of plated bodies have to react with electrolyte and become irreversibly oxidized. This has been shown by others using incremental capacity analysis (ICA, aka dQ/dV). For example, a lithium-ion battery may be slightly overcharged or fast charged so as to intentionally induce the plating of some lithium on the anode. Subsequently, following a discharge, the surface can be analyzed in ICA format from a slow charge at about C/2 or less, to observe a small peak associated with plated lithium preceding the start of intercalation at lower voltages. If the battery is instead rested for five minutes before starting the C/2 charge, the peak is no longer present. This is because the plated lithium has had sufficient time to oxidize and become electrically isolated from the electrode.

Clearly, the expediency and sensitivity with which plated lithium can be detected, even in very small amounts, may be important to avoid and reverse the potential loss of lithium inventory. If caught early enough, knowing when to implement any of the recovery methods described above may lead to highest possible yield of recovery in a manner of seconds or less with minimal disruption to the overall charging process.

Further, the ability to measure the condition of the surface with high sensitivity using the methods described herein allows all of these mechanisms to be applied in a prescribed and controlled manner rather than taking an empirically derived or general (non-adaptive) approach. The latter approach may cause other forms of aging and damage to the battery if reverse currents are too high, or result in costly or overengineered hardware to achieve outcomes which could be realized with lower power and lower cost hardware and with less wear to the battery if a feedback process guided the process.

In one example, the system detects the onset of plated material during charging, reflected by a measured change in the kinetic processes occurring as well as a change in the surface state of the anode. The system immediately stops the charge and waits for a small period, 0.01 to 5 seconds, to continue measurements and determine if the material is being recovered at an acceptable rate by intercalation. If so, the rest period continues until both measurements reflect more optimal conditions for cell and electrode health. If the recovery is too slow, a recovery signal with some degree of discharging current may be applied to encourage dissolution of the material. The recovery signal, and the magnitude of any currents, may be carefully increased from a small value, e.g., C/20, and controlled to avoid other forms of wear to the components of the cell while also monitoring precisely when lithium begins to leave the anode. In this way current and voltage magnitudes are as effective and efficient as possible. This process may continue for less than one minute, usually closer to several seconds, before measurements indicate a return to optimal surface conditions and kinetic processes, at which point the charging can be resumed with negligible loss to overall lithium inventory.

In contrast, if conventional state of the art methods based upon EIS and frequency response were used to detect these phenomena, they would not be able to detect changes in impedance until a significant amount of plating and irreversible oxidation had already occurred. Further, this approach would not inform an optimal method of recovery of any remaining and recoverable lithium.

### Lithium Plating and Anode Overpotential

Anode overpotential is a measure of the difference between the actual potential of the anode and its equilibrium potential. In an ideal scenario, during charging, lithium ions should deposit and intercalate into the anode at a consistent voltage, corresponding to the anode's equilibrium potential. In practice, due to various factors, including resistance in the electrolyte and at the anode-electrolyte interface, the actual voltage required to drive lithium deposition is often higher than the equilibrium potential. This voltage difference is the anode overpotential.

The occurrence of lithium plating is closely linked to the anode overpotential. When the anode overpotential drops to zero or becomes negative, there is not enough voltage to drive the lithium ions into the anode material as intended. This condition can lead to lithium plating. However, outside of a controlled lab environment, measuring anode overpotential in real-time to indicate cell degradation in a full lithium-ion battery may not be practical at least due to expenses, the possible need for additional connections, in addition to the conventional two connections to the anode and cathode for charge and discharge, to and into the cell structure of the battery among other requirements and hurdles.

Aspects of the present disclosure involve a novel method to obtain data from the battery and calculate a parameter, such as an electrodynamic parameter including the Lyapunov Exponent (LE) or the Correlation Dimension (CD), or information indicative of the parameter, from a response of the battery cell stimulated by a probing signal to provide insights into cell health and degradation in real time. In one example, the parameter is strongly correlated to anode overpotential, and based upon the parameter value, charging may be momentarily halted and or one or more discharge pulses initiated to halt and reverse lithium plating, among other advantages.

### Cell Probing and LE Calculation

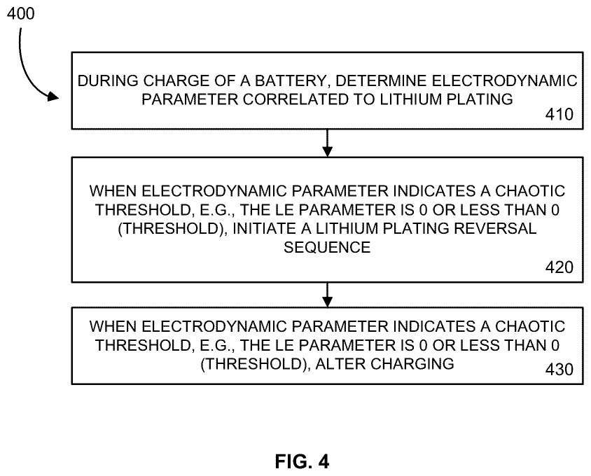

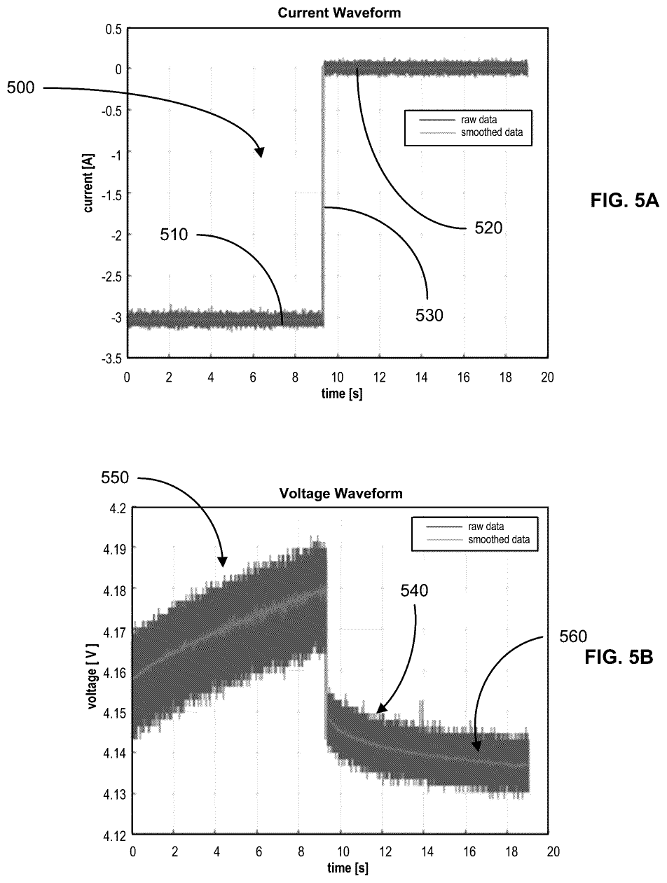

Aspects of the present disclosure involve a method for optimally charging a battery to reduce or avoid battery degradation and detect the onset of plating and reverse some or all of the same. Referring to FIG. 4, a method 400 begins with obtaining an electrodynamic parameter or other measurement or computation correlated with the lithium plating (operation 410). In one specific example of obtaining an electrodynamic parameter correlated to the onset of lithium plating, the battery is probed to generate data from which a parameter may be computed. In one example, the battery is probed with a unipolar pulse waveform, an example of which is shown in FIG. 5(A). The probing waveform may be a charge signal or portion of a charge signal, may be a distinct probe signal, or may be initiated in conjunction with charging or discharging, or otherwise. The probing waveform may also be a discharge pulse. In the example of FIG. 5(A), the probing waveform 500 involves a charging portion 510 and a rest period 520 with a transition 530 between the same. In the example, the duration (period) of the whole current probing waveform is 20 sec. including a 10 second charging portion and a 10 second resting portion. In the example illustrated, the magnitude of charging current is 3 A. It should be recognized that the probing waveform may vary in duration, shape, the charging portion and/or rest period may vary, and the current levels may vary depending on various factors including the type of battery.

Using data, e.g., voltage and/or current measurements from the battery, based on the probing signal, an electrodynamic parameter (or other parameter correlated to lithium plating) is computed or otherwise determined. In one example, the measurements may be conducted during a charging period 510 of the probing signal. In another example, the measurements may be conducted very shortly after the probing signal transitions 530 to the rest period 520. At this time, the current drops immediately to zero and the voltage transitions 540 from a relatively higher voltage 550 while under charge, as shown in FIG. 5(B), over about 6 seconds to the battery voltage 560. In the transition from an active signal, which may be the charge current, to rest, the anode overpotential drops and other battery states are less active and hence the information related to anode overpotential may be more prevalent in this transition period 540. In one specific example, the system computes the electrodynamic LE parameter or obtains a value or values indicative of the Lyapunov Exponent. While it is possible to compute the Lyapunov Exponent directly, it is also possible to use a proxy for the same. In one specific example, the voltage waveform, which may be in time voltage value pairs of a time series data, is captured during the relaxation period 520 after the current is turned off and the time series is used to compute the Lyapunov exponent. The utilization of Lyapunov exponent calculation is correlated with cell degradation, and hence can be used as discussed herein to manage initiating of plating reversal sequence.

The LE is a mathematical concept used to measure the sensitivity of a dynamical system to small perturbations. It is a measure of the average rate of divergence or convergence of nearby trajectories in phase space, where phase space is the space of all possible states of the system.

More precisely, the LE is defined as the limit of the logarithm of the ratio of the separation between two nearby trajectories to their initial separation, as the separation goes to zero. Mathematically, it can be expressed as follows:

$$λ = lim\_ \{ t -> ∞ \} ( 1 / t ) * log ( ‖ δ x ( t ) ‖ / ‖ δ x ( 0 ) ‖ )$$

where λ is the Lyapunov Exponent, t is the time, δx(t) is the separation vector between two nearby trajectories at time t, and δx(0) is the initial separation vector between the two trajectories.

In simpler terms, the LE measures the average rate at which nearby trajectories in phase space diverge or converge over time. If λ is positive, the trajectories diverge exponentially and the system is said to be chaotic, indicating that small differences in initial conditions can lead to vastly different outcomes over time. If λ is negative, the trajectories converge exponentially and the system is stable, indicating that small differences in initial conditions will converge over time.

The system can estimate Lyapunov exponent from voltage waveform V(t) (e.g., from voltage measurements collected from a probing waveform, during charge or otherwise) by the following steps:
Step 1. Embedding: The system first embeds the time series v(t) into a higher dimensional space (m dimensions) using lagged values:

$$X ( t ) = ( V ( t ) , V ( t + Δ t ) , … , V ( t + ( m - 1 ) Δ t ) )$$

where Δt is the time lag.
Step 2. Neighbor Selection: The system identifies nearby initial conditions in the embedded space, represented by vectors X_i(t) and X_j(t). These represent similar states of the system at a specific time (t).
Step 3. Trajectory Divergence calculation: The average rate of divergence between these trajectories is captured by the largest Lyapunov exponent (λ₁). The system can estimate it by calculating the average exponential separation distance between nearby points over time (t and t+Δt):

$${λ}_{1} \approx lim\_ ( Δ t -> 0 ) ( 1 / Δ t ) * ln ( ‖ X\_i ( t + Δ t ) - X\_j ( t + Δt ) ‖ / ‖ X\_i ( t ) - X\_j ( t ) ‖ )$$

where |·| denotes the norm (distance) between vectors.

The LE is a fundamental concept in chaos theory and provides insight into the long-term behavior of complex systems and can help predict the stability or instability of a system over time. Aspects of the present disclosure involve the unique recognition that the LE is strongly correlated to anode overpotential. And, hence, the Lyapunov Exponent may be used as indicator of lithium plating, and charge (or discharge) control altered based on the same.

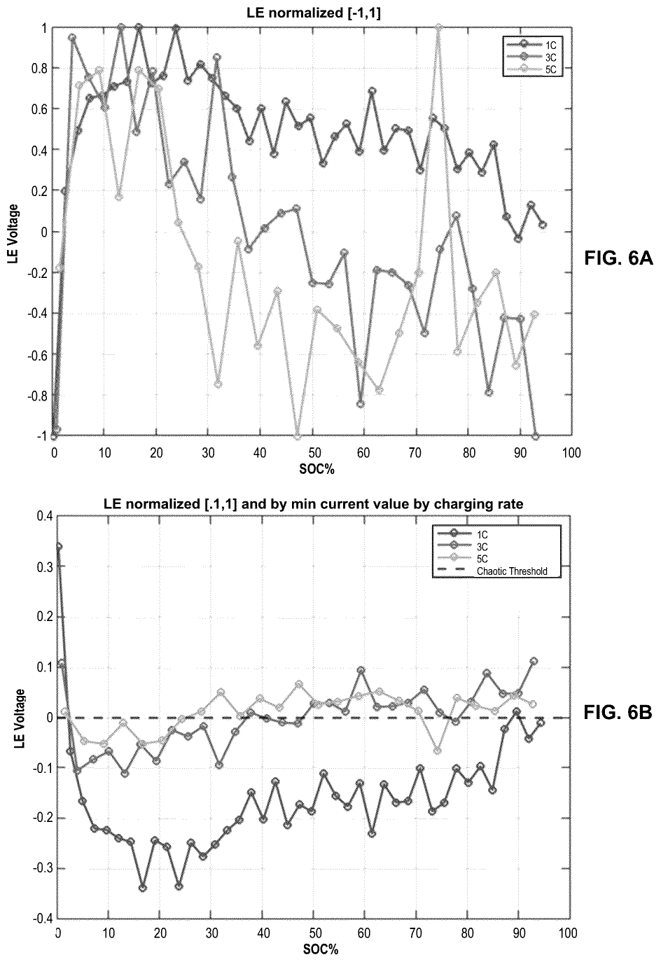

FIG. 6(A) shows the LE calculation based on voltage measurements taken during the transition period between rest and charging of the probing waveform. In the example probing waveform, voltage and current measurements are made around 10 seconds where the probing waveform transitions 530 from charging 510 to rest 520. Stated differently, the LE is calculated from voltage measurement taken on the back edge of the probing waveform. In the example of FIG. 6(A), the LE computations are done at different states of charge during the charge process. The LE values shown in the example are for a new, less than 10 previous cycles, 3 Ah Lithium-Ion battery cell with different charge rates of 1C, 3C and 5C. The LE values are normalized to [−1, 1] for comparison purpose. It can be seen that the LE curves with different charge rates begin diverging at around 20% SOC. The first 20% of charge at various rates appears sustainable with comparable degradation, and most of that early behavior is dominated by the cell's high impedance (which decreases at higher SOCs).

FIG. 6(B) presents the information of FIG. 6(A) in different form. Here, the LE computations are normalized to [−1,1] then divided by the minimum current value of each charging rate (1C, 3C and 5C), respectively. By normalizing the raw LE with current (negative current for charging), the sign of LE is flipped. So, here, the positive LE or value around 0 indicates chaotic behavior or related to lithium plating. For a 1C charge rate, the whole LE curve is below 0 reference line, which indicate a health charging. For a 3C charge rate, lithium plating begins at around 50% SOC where the LE start approaching zero. For a 5C charge rate, lithium plating begin at around 25% SOC where the LE start approaching zero. Here, LE approaching or reaching zero may be used as a threshold to trigger a lithium plating reversal sequence—rest, discharge pulse, and/or electric field in the various forms discussed herein.

The plots show us that at higher charge rates, the LE value decreases more rapidly. This indicates more severe cell degradation at higher charge rates. In FIG. 6(B), the LE values exceed a chaotic threshold at about 24% SOC when charging at 5C, exceed the chaotic threshold at about 38% when charging at 3C, and does not exceed the chaotic threshold until about 90% when charging at 1C. The chaotic threshold may be set as a threshold value that triggers a lithium plating reversal sequence. For example, a threshold of an LE Voltage value of 0 may be the threshold, or some value within a small percentage to avoid actually reaching the chaotic threshold. Other electrodynamic parameters may be computed, and threshold sets accordingly.

Referring back to FIG. 4, the method (and a charging system configured to perform the method) involves initiating a plating reversal sequence when an electrodynamic parameter indicates that a chaotic threshold is met (operation 420). Various forms of plating reversal sequences are discussed in detail below. Alternatively, or additionally, the method (and the system) may also involve altering the charge based on the chaotic threshold (operation 430). In some instances, the charge may proceed at a different rate after the reversal sequence or separately when the chaotic threshold is me. In a simple example, it can be seen that a slower rate may delay the onset of plating; thus, upon determining that a chaotic threshold is met, the system may reduce the charge rate. The system may also proceed with a relatively lower charge rate after a plating reversal sequence.

As noted above, whether to initiate a change in charge rate and/or lithium plating reversal sequence, may also be informed by additional information such as SOC or temperature.

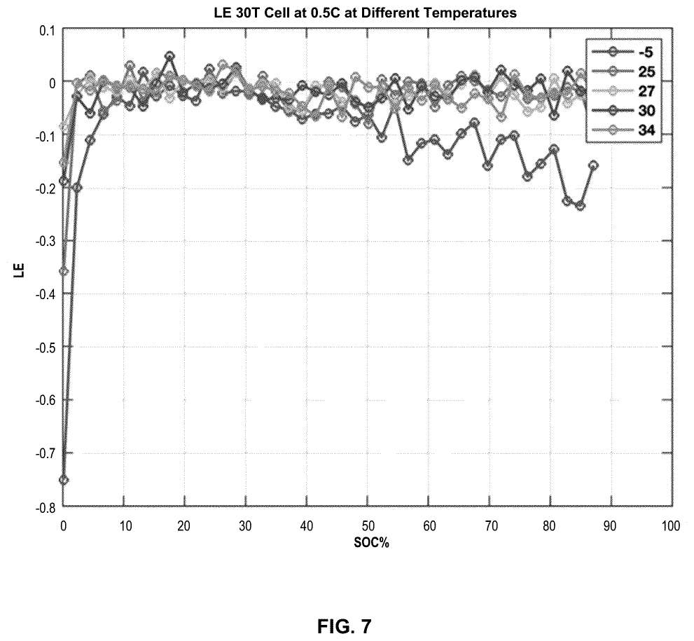

The information in the charts of FIGS. 6A, 6B and 7 reveals that initiating a plating reversal sequence alone or in combination with altering charge rate based on approaching the chaotic threshold for LE, may be used to reverse lithium plating as well as prevent or reduce battery degradation. Stated differently, by understanding the correlation between an electrodynamic parameter and the onset of lithium plating, the system may be configured to initiate a plating reversal sequence based on approaching or reaching the chaotic threshold of the electrodynamic parameter (here LE), and there is some dependence on charge rate and thus the system may also alter charge signals based on the same.

In FIG. 7, a 3 Ah cell was charged with a 0.5C charge rate at different temperatures. It can be seen that at higher temperatures (25° C., 27° C., 30° C., and 34° C.), the LE values are close to zero which indicates non-significant cell degradation. However, at a relatively lower temperature (−5° C.), the LE value decreases below 0 beginning at around 30% SOC, indicating the onset of plating and significant cell degradation due to low temperature. This also reveals that a plating reversal sequence may be initiated based on approaching or reaching the chaotic threshold, and there is some dependence on temperature and thus temperature, as well as SOC, may be used in conjunction with an electrodynamic parameter or other indicator of breaching a chaotic threshold to control charging and/or initiate a plating reversal sequence. Similarly, the onset of plating early in a charge cycle under relatively cold conditions may indicate that the charge current (here C/2) be reduced even further until the battery is able to warm up to safer temperatures where plating may be avoided.

### Correlation Between Anode Overpotential and LE Calculation

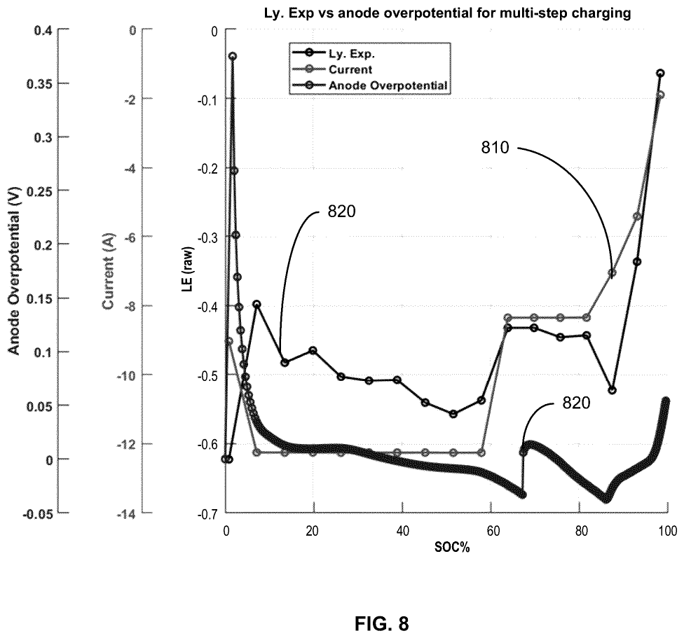

In further support of using LE as trigger for charge control (e.g., LE calculation from data gathered during the probing waveform) based on the LE being a lithium plating indicator is the strong correlation between LE and anode overpotential, shown in FIG. 8. As discussed, a negative anode potential triggers lithium plating in lithium-ion batteries. FIG. 8 shows the charging current (curve 800), anode overpotential (curve 810) and Lyapunov Exponent (curve 820) of a multi-step CCCV charging process on a 3 Ah cell. The current curves 810 shows the cell was charged with a 12.2 A constant current from about 5% SOC until about 60% SOC, then charged with an 8.4 A constant current from about 60% SOC to about 81% SOC, at which time the charging scheme changed to a constant voltage charge where the terminal voltage of the battery was held constant by steadily reducing the charge current. During charging, LE 820 was computed in 5% SOC intervals. In one example, charging may be discontinued for a very short period, and a probing signal injected into the battery as discussed above. In another example, the charge current may be altered, e.g., turned off for some time, e.g., 10 seconds, and battery measurements taken at the transition from charge current to 0 or some relatively lower charge current. Besides being useful for probing, the transition to a rest period may also halt plating and initiate recovery.

The anode overpotential plot 820 is a simulated anode overpotential based on the charging current profile using a PyBaMM model of the 3 Ah cell. It can be seen that the anode overpotential kept decreasing during the first stage of charging (12.2 A charging). Anode overpotential dropped to zero at around 20% SOC indicating the onset of lithium plating. At this point, a lithium plating reversal sequence may be initiated and/or the charge altered. However, in the case of the plot of FIG. 8, the system was gathering data and hence a reversal sequence or change in charge was not initiated—instead, the preprogrammed CCCV sequence continued. At 60% SOC, when the charging current was reduced to 8.4 A, the anode overpotential immediately increased to slightly above zero, and then almost immediately began decreasing again below zero. Since the charge current at this time was still relatively high, e.g., compared to a 1 C charge rate discussed above, the anode overpotential quickly decreased into negative condition where plating continued. Prior to entering a negative condition, a plating reversal sequency may be initiated. Moreover, charging may transition to a lesser current, which appears to slow or stop lithium plating due to the increase in anode overpotential, if even briefly. Although perhaps an unlikely charge situation due to the rapid change into a plating situation, the time at or near when LE reaches 0 may again trigger a plating reversal sequence. Any reversal sequence may also be associated with a change in the charge control. The overpotential again began to increase after the charge process entered into constant voltage stage sequence at about 80% SOC, where the charge current was steadily decreasing and the anode overpotential transitioned back into a positive value toward the end of charge at a charge current of around 6 A and less (about 97% SOC) at end of charge. Here, it can be observed that the LE curve 820 strongly correlates with anode overpotential 820 during the whole charging process making it possible to use LE as an indicator, which may be considered real-time, of lithium plating and a trigger to initiate a plating reversal sequence.

### Plating Reversal Controller Based on Real-Time Cell Degradation Feedback

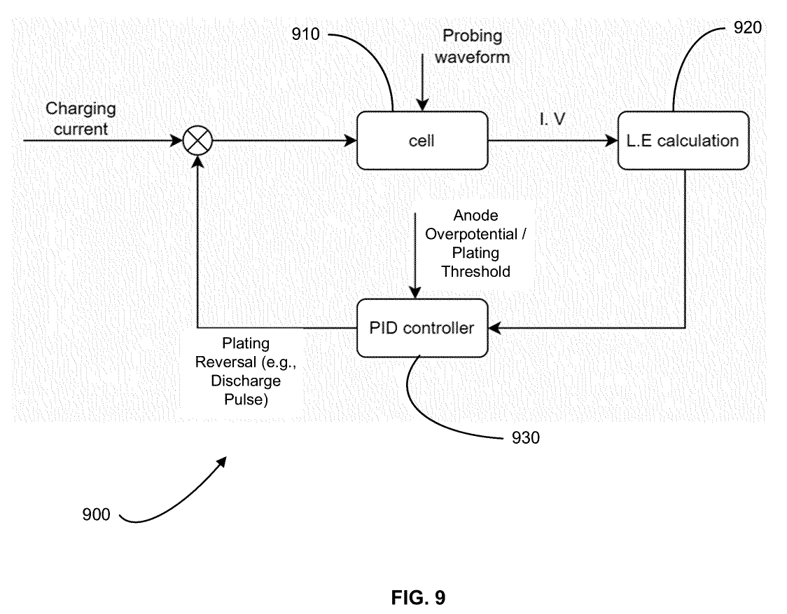

Given the information presented above, an example of a system for controlling charge of a battery is shown in FIG. 9. The system is configured to control charging including initiation of a plating reversal sequence based on real-time cell degradation feedback. In general, the controller implements a method of real-time monitoring of plating and more generally battery degradation through LE calculation based on measurements of the battery taking in the presence of a probing waveform, and initiates a plating reversal sequence and/or adjusts charging current dynamically to reverse plating, and otherwise optimize battery performance and extend lifespan. The method and variations of the same can be implemented in other controllers, with FIG. 9 presenting one possible example.

FIG. 9 shows a block diagram of a battery system 900 including a controller. The probing waveform is applied to a battery cell 910, and current (I) and voltage (V) probing waveform measurements are used to calculate an LE value (or values) 920, which will be sent to a proportional-integral-derivative (PID) controller 930 as inputs. A lithium plating threshold or more generally cell degradation threshold is set as a target value (e.g., 0, or −0.1 corresponding to values of the same for LE) for the PID controller. The target value may be set at 0 or a negative value (less than 0). The target value may also be set as a rate or more generally to a rate at which a value is approaching 0 alone or in conjunction with reaching 0. In such an example, if LE is approaching zero from a positive value, the threshold may initiated a plating reversal just prior to reaching zero or reaching a negative value. Of course, if values are normalized, scaled, etc., or otherwise filtered or processed, the use of a positive or negative reference may not be relevant. Stated differently, it should be recognized that should normalization, averaging or other computations occur that convert the value to a magnitude (without positive or negative connotations), the takeaway is that negative LE values in the sense of the difference between positive and negative LE computations are intended. Moreover, the discussed thresholds are illustrative of identifying when the LE value reaches or transitions from a value indicative of order to a value indicative of chaos or otherwise unordered behavior. Other electrodynamic parameters identifying the onset of chaotic behavior may also apply and be used in place of LE. Based on the difference between the calculated LE value and the target value, the PID controller initiates a plating reversal sequence. The PID controller may also, after plating reversal or as a separate routine, may output an adjustment to the charging current and apply the optimal charging current to the battery cell, and iterate the application of the same to optimize charge rate (speed) while reversing plating and otherwise charging without damaging the battery.

Conversely, the PID controller may optimize charging based on a threshold, and independently or in conjunction with adjusting charging current, the system may also initiate a plating reversal sequence as LE approaches 0, reaches 0, or is negative or otherwise indicates the onset of chaotic behavior.

### Lithium Plating Reversal Sequence Examples

As discussed, the method and system may initiate a plating reversal sequence when an electrodynamic parameter meets a threshold indicated of lithium plating (operation 420). A plating reversal sequence may take on many forms. In one example, a plating reversal may be an initiation of a rest period where no positive charging current is applied to the battery. The length of the rest period may be preset or may be based on continuing measurement of an electrodynamic parameter such as LE, and continuing the rest period until LE suggests lithium plating is no longer occurring or reversed (e.g., LE transition to 0, trends to positive, or is positive). If and/or when LE returns to a condition indicative of a positive anode overpotential, charging may resume.

In another example of a plating reversal sequence, the rest period may also be used in combination with a discharge sequence, change in charge current, and/or a sequence of rest periods and discharge pulses. So, for example, after a rest period, the system may initiate a discharge pulse of some magnitude and duration. The reversal sequence may end after the discharge, or the system may iterate between rest and discharge pulses with LE determinations initiating ongoing rest periods and/or discharge pulses until LE suggests a positive anode overpotential.

In another example, a plating reversal sequence may involve a discharge pulse. As noted, a discharge pulse is understood to reverse some plating. The discharge pulse may be deployed prior to or after a rest period, or independently of a rest period. The discharge pulse may be of varying magnitudes, varying length and/or a series of discharge and rest periods initiated as a duty cycle of discharge pulses. The discharge pulse may also be shaped such as including a shaped leading and/or trailing edge. The edges of the discharge pulse may approximate a harmonic or otherwise be of a lower frequency shape as compared to a very high frequency edge associated with a square pulse or square wave.

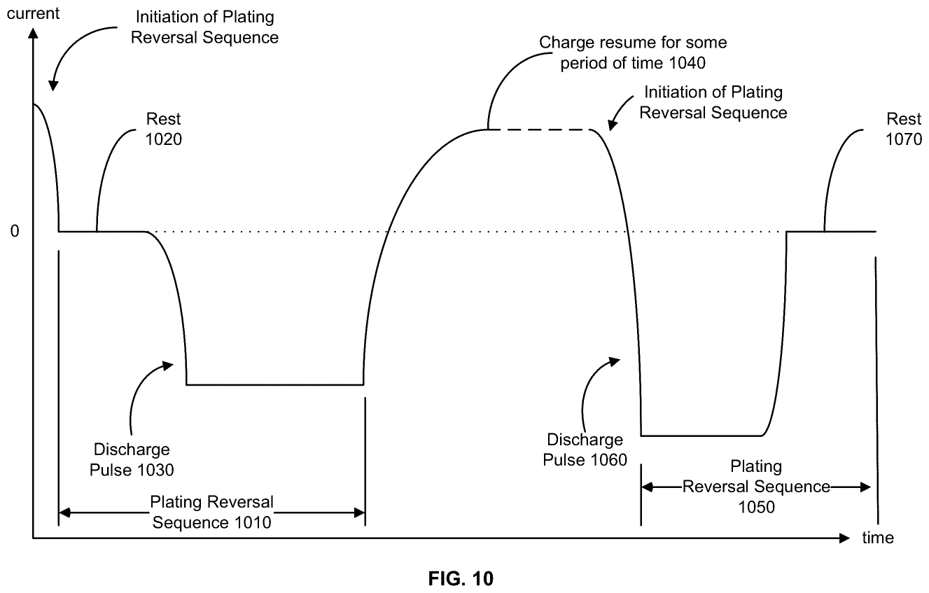

FIG. 10 illustrates some possible examples of reversal sequences. The illustrated sequences are meant to provide some examples of possible sequences, and different attributes of the same. The various possible sequences and combinations of rest, discharge and/or charge may however take on many different forms not shown. Moreover, the reversal sequences are shown on the same plot but this is done simply to illustrate the different possible reversal sequences, and not meant to indicate that the illustrated combination of reversal sequences is preferred or would be necessarily deployed in the shown combination. Each rest, discharge, combination of rest and discharge, combination of charge and reversal sequence, etc., may be arranged in any number of other possible combinations with the rest time, discharge pulse magnitude, discharge pulse time, etc., tailored to a specific scenario or preset sequence.

When the onset of plating is detected, the system may initiate a reversal sequence. As discussed, the onset of plating may be detected from the LE approaching 0, reaching 0 or becoming negative, some proxy of LE, or other electrodynamic parameter or proxy. In the first example, a plating reversal sequence 1010 involves a rest period 1020 followed by a discharge pulse 1030. The plating reversal sequence is shown as a rest followed by discharge but it may be one or more such combinations (e.g., rest, discharge, rest, discharge or rest, discharge, rest). After the reversal sequence charging may stop or resume. In the illustrated example, charging resumes 1040, with a sloped non-linear leading edge, albeit a lesser charge current than at the initiation of the first plating reversal sequence. Charge may proceed from some period of time before another plating reversal sequence 1050 is initiated. The charge portion 1040 may be a constant current sequence, may involve one or more shaped charging waveforms, may be a constant voltage period or some other charge sequence. The following plating reversal sequence may be initiated after some period of time, based on SOC, based on temperature, based on characterization, and/or based on an electrodynamic parameter indicative of the onset or imminent onset of plating. For purposes of illustrating different plating reversal sequences, the second sequence begins with a discharge pulse 1060. The discharge pulse is of a greater magnitude than the first discharge pulse but of a shorter duration. A longer discharge pulse (e.g., 60 seconds or longer) may be more effective in reversing lithium plating—to dissolve dead lithium and migrate dead lithium to anode. In other instances, a shorter duration but larger magnitude pulse may prove more effective. Regardless, the magnitude and duration of a discharge pulse are tunable parameters. A rest period 1070 follows the discharge pulse in the second sequence. The sequence may or may not include a rest period. If it has a rest period, the rest period may vary in duration. Charging may resume after a period of time or may resume after assessing an electrodynamic parameter. As such, the system may include a probing pulse to gather measurements to compute an electrodynamic parameter. Depending on what the electrodynamic parameter reveals about the state of the battery, an additional lithium plating reversal sequence may be initiated, charging may resume at the same or a different level than previously, or charging may be terminated.

Besides various advantages already expressed concerning detecting and acting to halt or reverse lithium plating, by initiating a lithium plating reversal sequence and/or altering charge based on an electrodynamic parameter, the system may act in real-time and based on real-time data measurements, to act quickly and minimize any plating damage, reverse some or all plating, and act before some or all plating becomes irreversible.

Besides the examples illustrates in FIG. 10, as noted above, it is also possible to initiate an electric field to reverse plating. In such an arrangement, a plating reversal sequence involves creating an electric field across the battery and such that the field lines are across the plated surface, e.g., the anode encouraging lithium ions to move away from the plated surface. In a pouch cell arrangement with planar electrode structure, the field lines may be generated between similarly planar surfaces to produce field lines generally transverse the electrode, which may be at right angles. As noted, the current collectors of a cell may be energized by coupling a voltage to a tab or other conductor coupled with the current collector, and grounding or producing a counter potential at the opposing current collector or tab, depending on the cell arrangement.

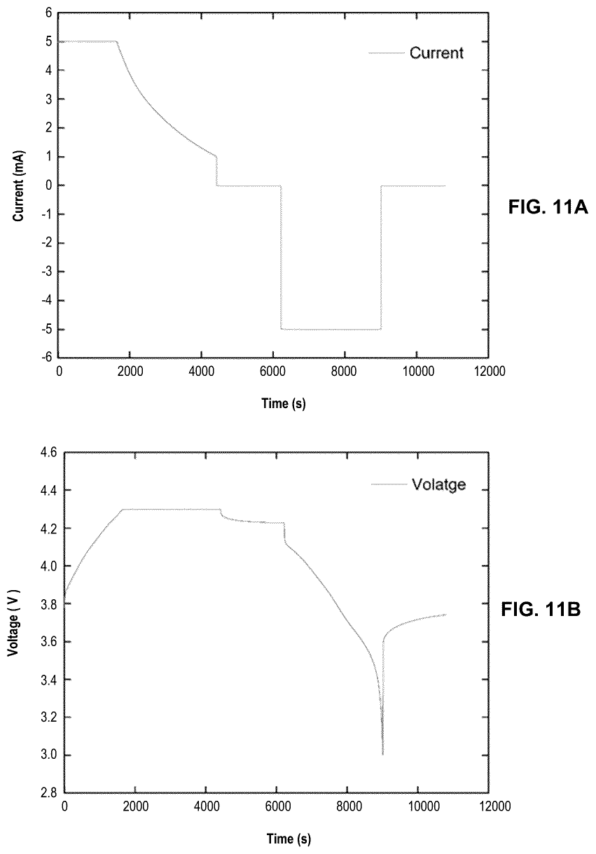

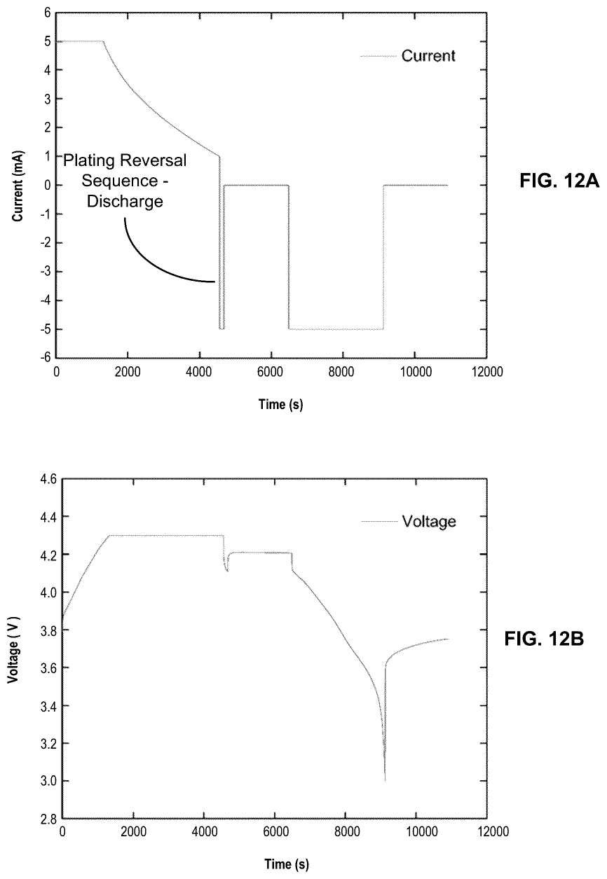

In order to validate the effectiveness of lithium plating reverse procedure. Two lithium metal half cells were made. The cathode electrode was made of lithium nickel cobalt manganese oxide (NCM). The anode electrode was made of pure lithium metal. The electrolyte is 1 mol concentration of LiPF6 salt in a mixture of ethylene carbonate (EC) and ethyl methyl carbonate (EMC) solvent. The first half cell marked as E1, was charged with CCCV protocol at a 1C rate (5 mA), followed by a 30 minutes rest period and a 1C rate discharged. The current and voltage profile are illustrated in FIGS. 11A and 11B. The second half cell marked as E5, was charged with the same protocol as E1. However, immediately after the half-cell was fully charged, the cell was discharged with a 1C rate for 2 minutes as shown in FIGS. 12A and 12B, then followed by a 30 minutes rest period and a 1C discharge process. The insertion of the discharge pulse immediately after the full charge was to reverse lithium platting caused by charging process.

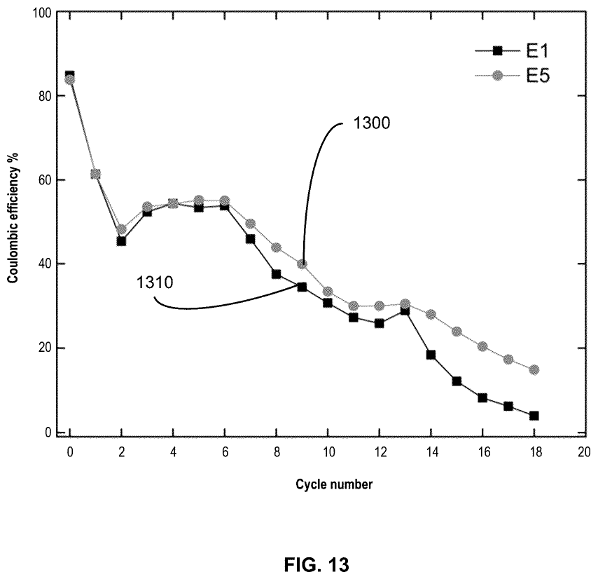

FIG. 13 shows the Coulombic efficiencies of the two half-cells during cycling. The Coulombic efficiency, which is defined by the ratio between discharge capacity vs charge capacity, is a measurement that reflects the effectiveness of the lithium plating reversal sequence (in this example, a 1C rate discharge pulse of 2 minutes). The half-cell E5 shows an overall higher Coulombic efficiency (line 1300) than the half-cell E1 (line 1310) and the difference became bigger and bigger with increase of cycle number. The higher Coulombic efficiency of E5 indicates some of the plating lithium was reversed and the lithium inventory was increased comparing to E1. The lithium plating reversal sequence was run after each charge cycle, which also illustrates the cumulative benefit of repeating the discharge cycle and the cumulative detriment of not running the plating reversal sequence.

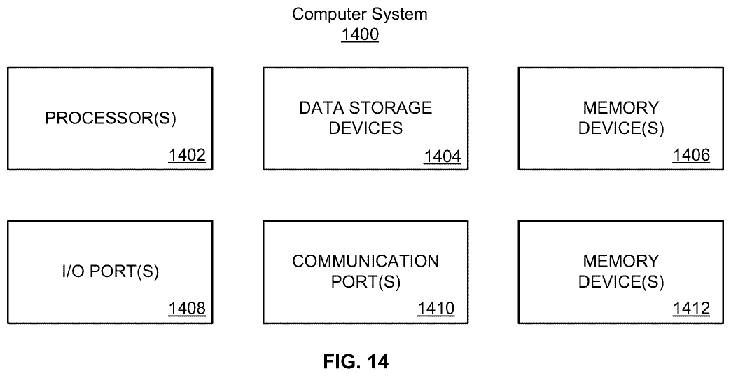

Referring to FIG. 14, a detailed description of an example computing system 1400 having one or more computing units that may implement various systems and methods discussed herein is provided. The computing system 1400 may be part of a controller, may be in operable communication with various implementation discussed herein, may run various operations related to the method discussed herein, may run offline to process various data for characterizing a battery, and may be part of overall systems discussed herein. More or fewer components of the system 1400 may be present in any possible implementation. In a system characterizing a battery or type of battery, a similar system may be involved as the system may be configured to implement various charge signals, process and analyze noise signals, and act on the same. User interfaces may also be involved to obtain inputs concerning the type of battery being characterized. In some applications, such as a power tool, relatively small mobile device like an e-bike, and some mobile computing applications, fewer or an otherwise more stripped-down system may be used. In some applications, system components of a wider system may be shared, such as in a mobile “smart” phone or tablet.

The computing system 1400 may process various signals (e.g., FIGS. 1, 2) discussed herein and/or may provide various signals discussed herein. For example, battery measurement information which is uncorrelated to any particular interpretation, or vague or incorrect interpretations using other methods such as Electrochemical Impedance Spectroscopy, Non-linear Electrochemical Impedance Spectroscopy, Equivalent Circuit Models, empirically derived neural network-based models, or models based primarily upon thermal and electrochemical physics, may be provided to such a computing system 400. The system may run transforms against the same and analyze the same. The system may characterize a battery using the same or may control some process such as charging or discharging. It will be appreciated that specific implementations of these devices may be of differing possible specific computing architectures, not all of which are specifically discussed herein but will be understood by those of ordinary skill in the art. It will further be appreciated that the computer system may be considered and/or include an ASIC, FPGA, microcontroller, or other computing arrangement. In such various possible implementations, more or fewer components discussed below may be included, interconnections and other changes made, as will be understood by those of ordinary skill in the art.

The computer system 1400 may be a computing system that is capable of executing a computer program product to execute a computer process. Data and program files may be input to the computer system 1400, which reads the files and executes the programs therein. Some of the elements of the computer system 1400 are shown in FIG. 4, including one or more hardware processors 1402, one or more data storage devices 404, one or more memory devices 1406, and/or one or more ports 1408-1412. Additionally, other elements that will be recognized by those skilled in the art may be included in the computing system 400 but are not explicitly depicted in FIG. 14 or discussed further herein. Various elements of the computer system 1400 may communicate with one another by way of one or more communication buses, point-to-point communication paths, or other communication means not explicitly depicted in FIG. 14. Similarly, in various implementations, various elements disclosed in the system may or not be included in any given implementation.

The processor 1402 may include, for example, a central processing unit (CPU), a microprocessor, a microcontroller, a digital signal processor (DSP), and/or one or more internal levels of cache. There may be one or more processors 1402, such that the processor 1402 comprises a single central-processing unit, or a plurality of processing units capable of executing instructions and performing operations in parallel with each other, commonly referred to as a parallel processing environment.

The presently described technology in various possible combinations may be implemented, at least in part, in software stored on the data stored device(s) 1404, stored on the memory device(s) 1406, and/or communicated via one or more of the ports 1408-1412, thereby transforming the computer system 1400 in FIG. 14 to a special purpose machine for implementing the operations described herein.

The one or more data storage devices 1404 may include any non-volatile data storage device capable of storing data generated or employed within the computing system 1400, such as computer executable instructions for performing a computer process, which may include instructions of both application programs and an operating system (OS) that manages the various components of the computing system 1400. The data storage devices 1404 may include, without limitation, magnetic disk drives, optical disk drives, solid state drives (SSDs), flash drives, and the like. The data storage devices 404 may include removable data storage media, non-removable data storage media, and/or external storage devices made available via a wired or wireless network architecture with such computer program products, including one or more database management products, web server products, application server products, and/or other additional software components. Examples of removable data storage media include Compact Disc Read-Only Memory (CD-ROM), Digital Versatile Disc Read-Only Memory (DVD-ROM), magneto-optical disks, flash drives, and the like. Examples of non-removable data storage media include internal magnetic hard disks, SSDs, and the like. The one or more memory devices 406 may include volatile memory (e.g., dynamic random-access memory (DRAM), static random-access memory (SRAM), etc.) and/or non-volatile memory (e.g., read-only memory (ROM), flash memory, etc.).

Computer program products containing mechanisms to effectuate the systems and methods in accordance with the presently described technology may reside in the data storage devices 1404 and/or the memory devices 1406, which may be referred to as machine-readable media. It will be appreciated that machine-readable media may include any tangible non-transitory medium that is capable of storing or encoding instructions to perform any one or more of the operations of the present disclosure for execution by a machine or that is capable of storing or encoding data structures and/or modules utilized by or associated with such instructions. Machine-readable media may include a single medium or multiple media (e.g., a centralized or distributed database, and/or associated caches and servers) that store the one or more executable instructions or data structures.

In some implementations, the computer system 1400 includes one or more ports, such as an input/output (I/O) port 1408, a communication port 1410, and a sub-systems port 1412, for communicating with other computing, network, or vehicle devices. It will be appreciated that the ports 1408-1412 may be combined or separate and that more or fewer ports may be included in the computer system 1400. The I/O port 1408 may be connected to an I/O device, or other device, by which information is input to or output from the computing system 1400. Such I/O devices may include, without limitation, one or more input devices, output devices, and/or environment transducer devices.

In one implementation, the input devices convert a human-generated signal, such as, human voice, physical movement, physical touch or pressure, and/or the like, into electrical signals as input data into the computing system 400 via the I/O port 408. In some examples, such inputs may be distinct from the various system and method discussed with regard to the preceding figures. Similarly, the output devices may convert electrical signals received from computing system 1400 via the I/O port 1408 into signals that may be sensed or used by the various methods and system discussed herein. The input device may be an alphanumeric input device, including alphanumeric and other keys for communicating information and/or command selections to the processor 1402 via the I/O port 1408.

The environment transducer devices convert one form of energy or signal into another for input into or output from the computing system 1400 via the I/O port 1408. For example, an electrical signal generated within the computing system 1400 may be converted to another type of signal, and/or vice-versa. In one implementation, the environment transducer devices sense characteristics or aspects of an environment local to or remote from the computing device 400, such as battery voltage, open circuit battery voltage, charge current, battery temperature, light, sound, temperature, pressure, magnetic field, electric field, chemical properties, and/or the like.

In one implementation, a communication port 1410 may be connected to a network by way of which the computer system 400 may receive network data useful in executing the methods and systems set out herein as well as transmitting information and network configuration changes determined thereby. For example, charging protocols may be updated, battery measurement or calculation data shared with external system, and the like. The communication port 1410 connects the computer system 1400 to one or more communication interface devices configured to transmit and/or receive information between the computing system 400 and other devices by way of one or more wired or wireless communication networks or connections. Examples of such networks or connections include, without limitation, Universal Serial Bus (USB), Ethernet, Wi-Fi, Bluetooth®, Near Field Communication (NFC), Long-Term Evolution (LTE), and so on. One or more such communication interface devices may be utilized via the communication port 410 to communicate with one or more other machines, either directly over a point-to-point communication path, over a wide area network (WAN) (e.g., the Internet), over a local area network (LAN), over a cellular (e.g., third generation (3G), fourth generation (4G), fifth generation (5G)) network, or over another communication means.

The computer system 400 may include a sub-systems port 412 for communicating with one or more systems related to a device being charged according to the methods and system described herein to control an operation of the same and/or exchange information between the computer system 400 and one or more sub-systems of the device. Examples of such sub-systems of a vehicle, include, without limitation, motor controllers and systems, battery control systems, and others.

The system set forth in FIG. 14 is but one possible example of a computer system that may employ or be configured in accordance with aspects of the present disclosure. It will be appreciated that other non-transitory tangible computer-readable storage media storing computer-executable instructions for implementing the presently disclosed technology on a computing system may be utilized.

Embodiments of the present disclosure include various steps, which are described in this specification. The steps may be performed by hardware components or may be embodied in machine-executable instructions, which may be used to cause a general-purpose or special-purpose processor programmed with the instructions to perform the steps. Alternatively, the steps may be performed by a combination of hardware, software and/or firmware.

Various modifications and additions can be made to the exemplary embodiments discussed without departing from the scope of the present invention. For example, while the embodiments, also referred to as implementations or examples, described above refer to particular features, the scope of this invention also includes embodiments having different combinations of features and embodiments that do not include all of the described features. Accordingly, the scope of the present invention is intended to embrace all such alternatives, modifications, and variations together with all equivalents thereof.

While specific implementations are discussed, it should be understood that this is done for illustration purposes only. A person skilled in the relevant art will recognize that other components and configurations may be used without parting from the spirit and scope of the disclosure. Thus, the following description and drawings are illustrative and are not to be construed as limiting. Numerous specific details are described to provide a thorough understanding of the disclosure. However, in certain instances, well-known or conventional details are not described in order to avoid obscuring the description. References to one or an embodiment in the present disclosure can be references to the same embodiment or any embodiment; and, such references mean at least one of the embodiments.

Reference to “one embodiment” or “an embodiment” means that a particular feature, structure, or characteristic described in connection with the embodiment is included in at least one embodiment of the disclosure. The appearances of the phrase “in one embodiment”, or similarly “in one example” or “in one instance”, in various places in the specification are not necessarily all referring to the same embodiment, nor are separate or alternative embodiments mutually exclusive of other embodiments. Moreover, various features are described which may be exhibited by some embodiments and not by others.

The terms used in this specification generally have their ordinary meanings in the art, within the context of the disclosure, and in the specific context where each term is used. Alternative language and synonyms may be used for any one or more of the terms discussed herein, and no special significance should be placed upon whether or not a term is elaborated or discussed herein. In some cases, synonyms for certain terms are provided. A recital of one or more synonyms does not exclude the use of other synonyms. The use of examples anywhere in this specification including examples of any terms discussed herein is illustrative only and is not intended to further limit the scope and meaning of the disclosure or of any example term. Likewise, the disclosure is not limited to various embodiments given in this specification.

Without intent to limit the scope of the disclosure, examples of instruments, apparatus, methods and their related results according to the embodiments of the present disclosure are given below. Note that titles or subtitles may be used in the examples for convenience of a reader, which in no way should limit the scope of the disclosure. Unless otherwise defined, technical and scientific terms used herein have the meaning as commonly understood by one of ordinary skill in the art to which this disclosure pertains. In the case of conflict, the present document, including definitions will control.

Additional features and advantages of the disclosure will be set forth in the description which follows, and in part will be obvious from the description, or can be learned by practice of the herein disclosed principles. The features and advantages of the disclosure can be realized and obtained by means of the instruments and combinations particularly pointed out in the appended claims. These and other features of the disclosure will become more fully apparent from the following description and appended claims or can be learned by the practice of the principles set forth herein.

What is claimed:

1. A method comprising:
accessing a noisy signal from a battery, the noisy signal including uncorrelated noise and correlated signal data;
filtering the noisy signal to isolate the correlated signal data;
processing the correlated signal data to identify plating within the battery; and
initiating at least one of reducing charge, stopping charge, discharging the battery or generating an electric field to at least partially stop or reverse plating.

2. The method of claim 1 wherein the noisy signal is a voltage measurement.

3. The method of claim 1 wherein the noisy signal is a current measurement.

4. The method of claim 1 wherein the correlated signal data is associated with plating.

5. The method of claim 1 wherein the correlated signal data is further associated with dendrite formation and growth.

6. The method of claim 1 wherein processing the correlated signal data involves identifying a bifurcation, the bifurcation indicative of the onset of an additional electrochemical or electrodynamic process.

7. A method comprising:
from a signal of an electrochemical device including uncorrelated data and correlated data including pertaining to electrochemical or electrodynamic process of the electrochemical device, filtering the signal to identify the correlated data including information pertaining to the electrochemical or electrodynamic process; and
altering a charge parameter based, at least in part, on identification of a bifurcation in the filtered signal.

8. The method of claim 22 wherein the electrochemical device is a battery.

9. The method of claim 22 wherein the signal is measured during charge or discharge.

10. The method of claim 22 wherein the correlated data pertains to, at least in part, plating of the anode and altering the charge parameter reduces or reverses plating.

11. A method of managing plating in a battery comprising:
from a signal of a battery, computing a Lyapunov Exponent; and
initiating at least one of stopping charge of the battery, discharging the battery, or generating an electric field across the battery upon identifying that the Lyapunov Exponent has met a threshold associated with chaotic behavior.

12. The method of claim 11 wherein the threshold is a value of 0.

13. The method of claim 11 wherein the signal is a voltage signal.

14. The method of claim 11 wherein the signal is responsive to a probe signal to the battery.

15. The method of claim 11 wherein discharging the battery is for a duration of between 30 seconds and 3 minutes, after which charging of the battery resumes.

16. The method of claim 11 wherein stopping charge is followed by a discharge pulse.

17. The method of claim 11 wherein after stopping charge of the battery or discharging the battery, charging of the battery resumes at a charge magnitude less than a charge magnitude before identifying that the Lyapunov Exponent has met the threshold associated with chaotic behavior.
